(19) United States
(12) Patent Application Publication
(10) Pub. No.: US 2002/0076852 A1
(43) Pub. Date: Jun. 20, 2002

(54) Method for manufacturing a component which is encapsulated in plastic, and a component which is encapsulated in plastic

(76) Inventors: Stefan Paulus, Zeitlarn (DE); Albert Auburger, Regenstauf (DE); Oswald Hainz, Burglengenfeld (DE); Helga Hainz, Burglengenfeld (DE); Dietmar Lang, Regenstauf (DE); Martin Petz, Hohenkammer (DE); Michael Weber, Mainburg (DE)

Correspondence Address: LERNER AND GREENBERG, P.A., Post Office Box 2480, Hollywood, FL, 33022-2480, US

(21) Appl. No.: 09/962,697

(22) Filed: Sep. 24, 2001

(30) Foreign Application Priority Data
Sep. 22, 2000 (DE) 100 47 135.8

(51) Int. Cl. H01L 21/44

(52) U.S. Cl. 438/110

(57) ABSTRACT

A method for manufacturing a component is described and includes providing at least one integrated circuit with an active main side on which a multiplicity of contact pads of the integrated circuit are located. In a second step, the at least one integrated circuit is applied to a base substrate, the active main side facing the base substrate. The at least one integrated circuit which is applied to the base substrate is then encapsulated with a sealing compound. In a subsequent step, at least parts of the base substrate are removed from the at least one encapsulated integrated circuit. The contact pads of the at least one integrated circuit are connected to electrically conductive bumps which themselves are applied directly to the base substrate.

### BACKGROUND OF THE INVENTION

### FIELD OF THE INVENTION

The invention relates to a method for manufacturing a component which is encapsulated in plastic. The integrated circuit has an active main side with a multiplicity of contacts disposed on the active main surface. The integrated circuit is applied to a base substrate with the active main surface facing the base substrate. The integrated circuit is encapsulated by a sealing compound and at least parts of the base substrate are removed from the encapsulated integrated circuit.

The present invention is suitable for low-frequency or high-frequency applications in which the component has a small number of contacts. The components could be, for example, semiconductor switches, diodes or the like. However, the invention is readily also applicable with other types of components, for example with memory components or logic components.

In such components, the integrated circuits are usually mounted on metal lead frames or on laminate or ceramic substrates as chip carriers. Contacts are then made to the integrated circuit either using a wire bonding technique or a flip-chip technique. To provide mechanical protection, the integrated circuit is encapsulated, for example by pressing substances around it using transfer molding. The external contacts of the component are frequently located on the underside of the housing. Because these components then do not have any customary pin terminals, the term used is “leadless components” and “leadless chip carriers” (LCC). With such components it is possible to implement a considerably higher number of terminals (external contacts) in comparison to conventional configurations with the same area. Alternatively, given an equal number of external contacts in comparison with a component of a conventional configuration, it would be possible to achieve a significantly smaller area, in which case a smaller overall height would also be possible. As a result of the short signal paths and the compact configuration of the component, advantages are obtained especially with high-frequency applications. The small dimensions of the components also act favorably on the mechanical stress-bearing capability and the attachment to a substrate.

European Patent Application EP 0 773 584 A2 discloses various components which both dispense with the use of a metal lead frame with a ceramic substrate. The semiconductor components described in the publication have a housing made of a plastic sealing compound that surrounds the semiconductor chip. The external contacts are disposed here on a main face of the semiconductor component. A component in which the external contacts are constructed in the form of simple metalizations is shown, for example, in FIG. 35, the metalizations terminating flush with the main face of the semiconductor component. The contact pads for the integrated circuit are electrically connected to the metalizations using a flip-chip technique. The semiconductor component shown in the figure requires a very complex process sequence during its manufacture. However, the manufacture of individual semiconductors requires method steps that are as simple as possible and materials and housing configurations that are as cost-effective as possible.

### SUMMARY OF THE INVENTION

It is accordingly an object of the invention to provide a method for manufacturing a component that is encapsulated in plastic, and a component that is encapsulated in plastic that overcomes the above-mentioned disadvantages of the prior art devices and methods of this general type, which can be manufactured as easily as possible with known manufacturing methods, and which is constructed with a small number of external contacts resulting in compact external dimensions.

With the foregoing and other objects in view there is provided, in accordance with the invention, a method for manufacturing a component. The method includes the steps of providing at least one integrated circuit having an active main side with a multiplicity of contact pads disposed on the active main side, providing a base substrate, applying electrically conductive bumps to the base substrate, applying the integrated circuit to the base substrate such that the active main side faces the base substrate and the contacts pads of the integrated circuit are connected to the electrically conductive bumps, encapsulating the integrated circuit applied to the base substrate with a sealing compound resulting in an encapsulated integrated circuit, and removing at least parts of the base substrate from the encapsulated integrated circuit.

The manufacturing method according to the invention provides in a first step, that the at least one integrated circuit is produced with an active main side on which the multiplicity of contact pads of the integrated circuit are located. In a second step, the at least one integrated circuit is applied to the base substrate, the active main side of the integrated circuit facing the base substrate. In a third step, the at least one integrated circuit which is applied to the base substrate is encapsulated with the sealing compound. Then, at least parts of the base substrate are removed from the at least one encapsulated integrated circuit. According to the invention it is provided for the contact pads of the at least one integrated circuit to be connected to electrically conductive bumps which are applied directly to the base substrate.

In other words, the integrated circuit is applied to the base substrate using flip-chip technology, then encapsulated with a sealing compound, and in a further step the base substrate is removed. Because such a configuration can dispense with the use of bonding wires, a component that is reduced in thickness can be manufactured. The plastic housing ensures that the sensitive integrated circuit is protected. After the base substrate is removed, there are external contacts remaining on the underside of the component.

Materials known from the prior art can be used as the base substrate so that cost-effective manufacture is possible. In particular, a normal lead frame material, which is composed, for example, of copper, is possible.

By encapsulating the integrated circuit applied to the base substrate it is possible to freely determine the size of the resulting component. It is then possible to manufacture a component that is as small as possible in dimension. On the other hand, the size of the component can, however, also be adapted to existing machine tools, that is to say the encapsulation can have a surface starting from the surface of the integrated circuit.

In one refinement, the invention provides for the step of the application of the at least one integrated circuit to the base substrate to provide a connection of the bumps to the base substrate by thermocompression or alloying. In this way, the connection techniques known from the prior art can be applied.

The removal of the base substrate from the at least one encapsulated integrated circuit can be carried out by etching, delaminating, grinding or sawing.

In a first variant of the method according to the invention, the base substrate is completely removed, parts of the bumps being accessible on the underside of the encapsulated component and forming external contacts. The resulting component is thus only slightly larger than the integrated circuit and the bumps connected to the contact pads.

In a second variant of the method according to the invention, the bumps are applied to elevations on the base substrate that are constructed so as to be integral therewith or combined therewith, the elevations forming external contacts after the base substrate has been removed. The provision of the elevations on the base substrate, which form the external contacts of the completed component, permit the contact structure to be enlarged in comparison with a conventional flip-chip “footprint”. In particular, it is possible to select dimensions that can be applied in circuit board technology. In this way, the component can easily be applied to a further substrate and electric contact formed between it and said substrate.

After the removal of the base substrate, the external contacts are advantageously finished, i.e. provided with a solderable surface. In particular, further “solder bumps” or metal layers can he applied to the external contacts in order to permit a better connection to be formed to a further substrate.

A multiplicity of integrated circuits that are encapsulated with a sealing compound is advantageously applied to the substrate. After the integrated circuits are encapsulated, they are therefore all in a plastic housing. The encapsulated integrated circuits can subsequently be separated by sawing, cutting or by a water jet.

The bumps can be applied to the contact pads of the integrated circuit before the step of applying the at least one integrated circuit to the base substrate. Alternatively, before the step of applying the at least one integrated circuit to the base substrate, the bumps can be applied to the base substrate so as to correspond to the contact pads.

The component according to the invention has an integrated circuit that includes, on its active main side, contact pads which are connected to electrically conductive bumps. A sealing compound encapsulates the integrated circuit completely. According to a first variant, parts of the bumps on the underside of the encapsulated component are accessible and lie in a plane with the underside formed by the encapsulation and form external contacts.

In another variant of the component according to the invention, the bumps are connected to electrically conductive regions of the base substrate that are located in the sealing compound and are accessible on the underside of the encapsulated component by external contacts. The conductive regions of the base substrate constitute here the above-mentioned raised portions which are connected integrally to the base substrate. The conductive regions are constructed so as to have a flat, trapezoidal or T-shaped cross section.

Other features which are considered as characteristic for the invention are set forth in the appended claims.

Although the invention is illustrated and described herein as embodied in a method for manufacturing a component which is encapsulated in plastic, and a component which is encapsulated in plastic, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, cross-sectional view of a first exemplary embodiment of a component according to the invention;

FIG. 2 is a plan view of an underside of the component shown in FIG. 1;

FIGS. 3 to 6 are sectional views showing various method steps during the manufacture of the component;

FIG. 7 is a cross-sectional view of a second exemplary embodiment of the component;

FIG. 8 is a plan view of the underside of the component shown in FIG. 7; and

FIGS. 9 to 12 are sectional views showing various method steps during the manufacture of the component shown in FIG. 7.

### DESCRIPTION OF THE PREFERRED EMBODIMENTS

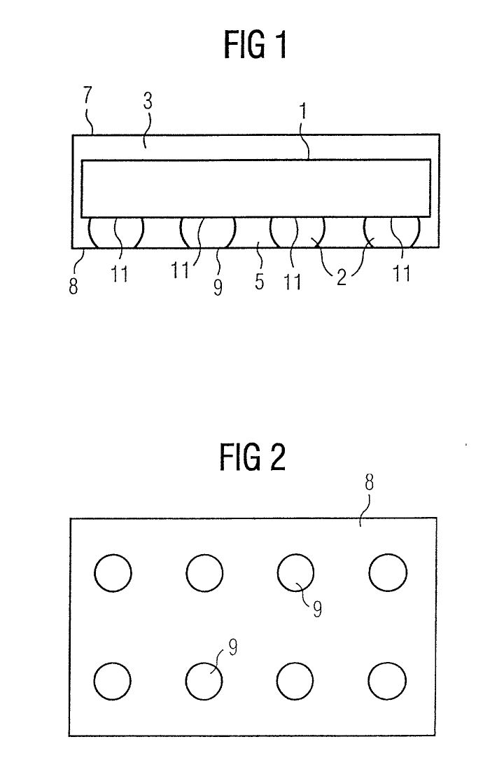

Referring now to the figures of the drawing in detail and first, particularly, to FIG. 1 thereof, there is shown a first exemplary embodiment of a component according to the invention in cross section. The latter is defined by the fact that the finished component is only slightly larger in dimensions than an integrated circuit 1 per se. FIG. 1 shows the integrated circuit 1 that has, for example, four contact pads 11 on its active main side 5. Bumps 2 are applied to the contact pads 11 in a known fashion. The integrated circuit 1 and the bumps 2 are surrounded by a sealing compound 3. The sealing compound 3 encapsulates the integrated circuit 1 in such a way that parts of the bumps 2 are accessible from an underside 8 of the component and form external contacts 9. It is clearly apparent from FIG. 2, which shows a plan view of the underside 8 of the component, that only those regions of the bumps 2 which were connected to the base substrate (described later) during the manufacturing process are accessible from the underside 8.

The component according to the invention has the advantage that it ensures that the integrated circuit 1 is mechanically protected, while its dimensions are larger to only an insignificant degree. In particular, a small overall height can be implemented with the component illustrated in FIG. 1 because it is possible to dispense with the use of bonding wires. Furthermore, corrosion protection is provided as a function of the configuration. The invention thus permits cheaper manufacture of a flip-chip component owing to its simpler component construction. In addition, during mounting on a substrate, no “underfill” is necessary. The sealing compound 3 itself is already capable of absorbing mechanical stresses, for example owing to different thermal coefficients of expansion.

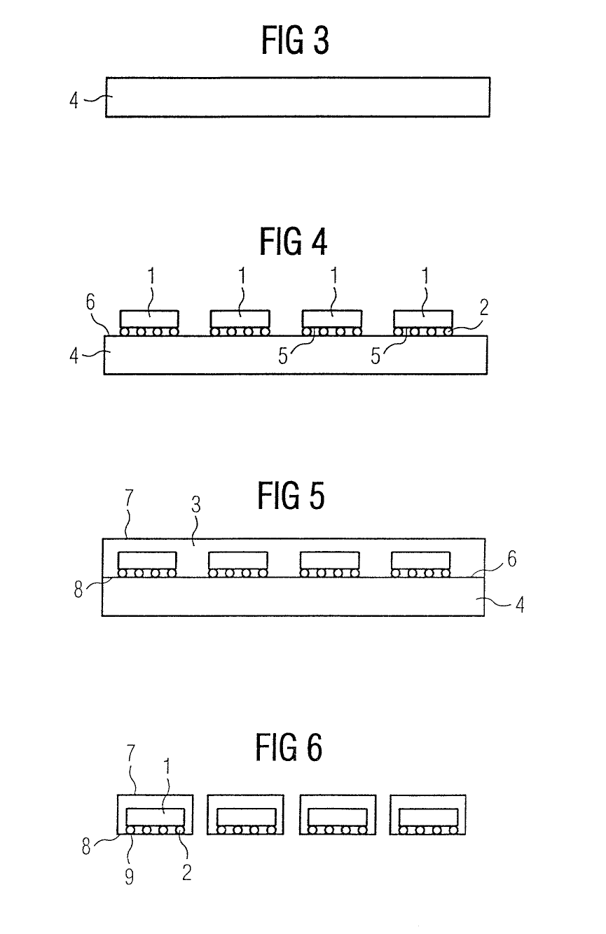

FIGS. 3 to 6 show various method steps for manufacturing the component according to FIG. 1. FIG. 3 illustrates just one base substrate 4 that has a planar surface in cross section. In a further method step (FIG. 4), a plurality of integrated circuits 1 are applied to an upper side 6. Here, their active surfaces 5 face the base substrate 4. Contact pads 11 of the integrated circuits 1 are connected here to the base substrate 4 via the electrically conductive bumps 2. The bumps 2 may have already been connected to the contact pads 11 before the application of the integrated circuits 1 to the base substrate 4. Alternatively, it would also be conceivable to apply the bumps 2 to the base substrate 4, in which case their configuration could be selected so as to correspond to the contact pads 11 of the integrated circuits 1. Only after that would it then be possible to apply the integrated circuits 1 to the bumps 2. The mechanical connection between the base substrate 4 and the bumps 2 could then be implemented by customary standard processes, for example thermocompression or alloying.

In a further method step according to FIG. 5, all the integrated circuits 1 located on the upper side 6 of the base substrate 4 are preferably encapsulated with the sealing compound 3. It would of course also be conceivable to provide each individual circuit of the integrated circuits 1 with a separate encapsulation.

In a further method step, the substrate 4 is removed from the encapsulated integrated circuits 1. The integrated circuits 1 that are located, as before, in a single encapsulation, can then be separated from one another, for example by sawing (FIG. 6).

As is apparent from the description above, not only does the finished component have advantages over conventional components, but it can also be manufactured with a small number of simple standard steps. In particular, the known manufacturing methods can be applied. In particular a simple lead frame carrier made of copper is possible as the base substrate 4. However, in principle any desired material can be used provided that a mechanical connection between the bumps 2 and the base substrate 4 is possible.

As is clear from FIG. 6 and FIG. 1, the external connections 9 terminate approximately flush with the underside 8 of the component. In order to be able to electrically connect such a component to a printed circuit board or some other type of substrate, it may be advantageous to cause the bumps to grow once more on the electrical contacts 9. The finishing of the electrical contacts 9 can be carried out for example by electro-plating by solder bumps or metal layers or chemically. The finishing of the external contacts 9 can be carried out here before the integrated circuits are separated.

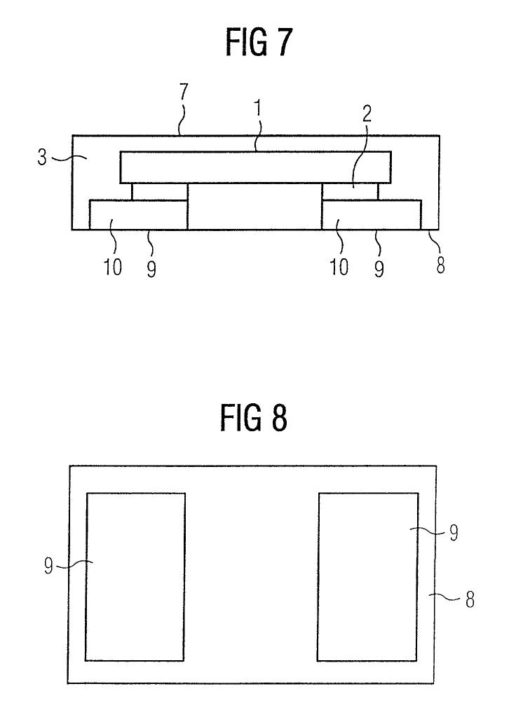

FIG. 7 shows a further exemplary embodiment of the component according to the invention. The integrated circuit 1 is connected to electrically conductive regions 10 via the electrically conductive bumps 2. The regions 10 finish at the underside, approximately flush with the encapsulation 3. By the conductive regions 10 it is possible to provide significantly greater electrical external contacts 9 in comparison with the first embodiment variant according to FIGS. 1 to 6. This is clear in particular from FIG. 8, which shows a plan view of the underside 8 of the component from FIG. 7.

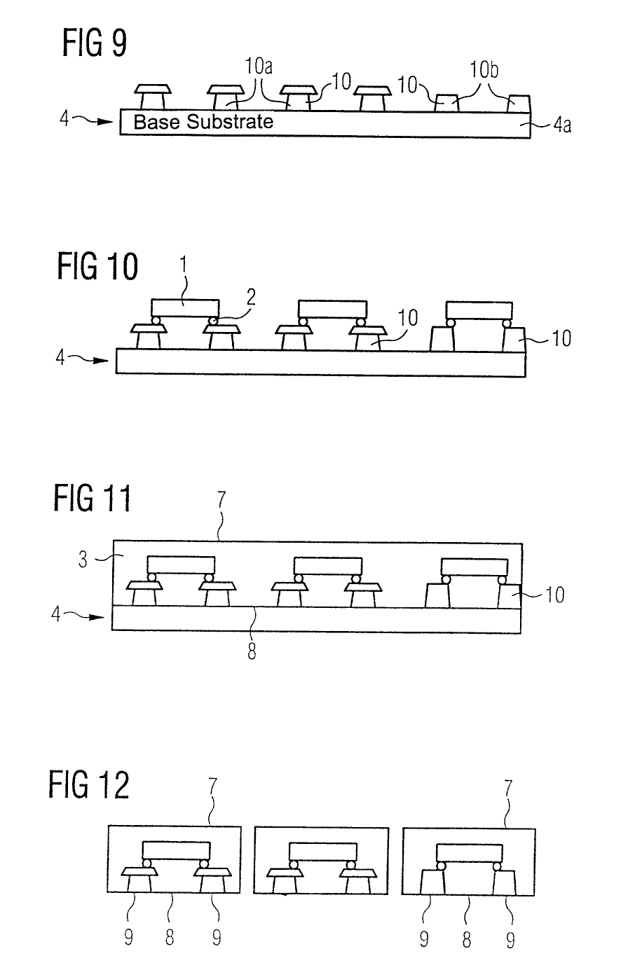

The manufacturing method is illustrated in FIGS. 9 to 12 in various method steps.

The base substrate 4 then has the electrically conductive regions in the formed of raised portions 10 on its upper side. These can be constructed so as to be T-shaped (see reference numeral 10a) or trapezoidal in cross section (see reference numeral 10b). According to the principle, such a raised portion 10 can have any desired shape provided that a distance from the main surface 6 of the base substrate 4 is ensured.

The bumps 2 of the integrated circuit 1 are then applied to the raised portions 10 and connected thereto by thermocompression or alloying. The multiplicity of integrated circuits 1 applied one next to the other to the base substrate 4 is then encapsulated with the sealing compound 3. This is followed by the removal of the base substrate 4, in which case, however, in the present exemplary embodiment the entire base substrate 4 with a base plate 4a and the raised portions 10 is not removed but rather only the base plate 4a. After the removal of the base plate 4a, the raised portions 10 are then within the encapsulated component.

The raised portions 10 then form the external contacts 9, as is apparent from FIG. 12. The base substrate 4 serves only as an intermediate carrier for mounting and is essentially removed.

In this way, the external contacts 9 can easily be enlarged in comparison with conventional flip-chip configurations. In particular, it is possible to implement the dimensions that are used in printed circuit board technology. The base substrate 4 that is embodied according to FIG. 9 can be constructed so as to be integral or combined. Copper is possible as the base plate 4a (substrate carrier). The T-shaped raised portions 10 can be composed of Ni/Au or other suitable materials.

The external contacts 9 according to the second variant of the invention can also be finished by electroplating or a chemical process.

We claim:

1. A method for manufacturing a component, which comprises the steps of:
providing at least one integrated circuit having an active main side with a multiplicity of contact pads disposed on the active main side;
providing a base substrate;
applying electrically conductive bumps to the base substrate;
applying the integrated circuit to the base substrate such that the active main side faces the base substrate and the contacts pads of the integrated circuit are connected to the electrically conductive bumps;
encapsulating the integrated circuit applied to the base substrate with a sealing compound resulting in an encapsulated integrated circuit; and
removing at least parts of the base substrate from the encapsulated integrated circuit.

2. The method according to claim 1, which comprises using one of thermocompression and alloying for applying the electrically conductive bumps to the base substrate.

3. The method according to claim 1, which comprises performing one of etching, delaminating, grinding and sawing the base substrate for performing the step of removing at least parts of the base substrate.

4. The method according to claim 1, which comprises completely removing the base substrate such that parts of the electrically conductive bumps are accessible on an underside of the encapsulated integrated circuit and form external contacts.

5. The method according to claim 3, which comprises:
providing the base substrate with elevations disposed thereon;
applying the electrically conductive bumps to the elevations disposed on the base substrate, the elevations forming external contacts after at least parts of the base substrate have been removed.

6. The method according to claim 4, wherein the external contacts are finished after a removal of the base substrate.

7. The method according to claim 1, which comprises applying a multiplicity of integrated circuits to the base substrate which are encapsulated with the sealing compound.

8. The method according to claim 7, which comprises separating the integrated circuits which are encapsulated jointly by one of sawing and cutting.

9. The method according to claim 1, which comprises applying the electrically conductive bumps to the base substrate so as to correspond to the contact pads before performing the step of applying the integrated circuit to the base substrate.

10. The method according to claim 5, which comprises forming the elevations as an integral part of the base substrate.

11. A method for manufacturing a component, which comprises the steps of:
providing at least one integrated circuit having an active main side with a multiplicity of contact pads disposed on the active main side;
providing a base substrate;
applying electrically conductive bumps to the contact pads of the integrated circuit;
applying the integrated circuit to the base substrate, the active main side of the integrated circuit facing the base substrate and the contacts pads with the electrically conductive bumps contacting the base substrate;
encapsulating the integrated circuit applied to the base substrate with a sealing compound resulting in an encapsulated integrated circuit; and
removing at least parts of the base substrate from the encapsulated integrated circuit.

12. A component, comprising:
an integrated circuit having a active main side with contact pads disposed on said active main side;
electrically conductive bumps connected to said contact pads; and
a sealing compound encapsulating said integrated circuit and parts of said electrically conductive bumps resulting in an encapsulated component having an underside, parts of said electrically conductive bumps being accessible on said underside of said encapsulated component, said parts of said electrically conductive bumps lying in a plane with said underside forming external contacts.

13. A component, comprising:
an integrated circuit having an active main side with contact pads disposed on said active main side;
electrically conductive bumps connected to said contact pads;
electrically conductive regions of a base substrate connected to said electrically conductive bumps;
a sealing compound encapsulating said integrated circuit, said electrically conductive bumps and parts of said electrically conductive regions resulting in an encapsulated component having an underside, said electrically conductive regions encapsulated in said sealing compound are accessible on said underside of said encapsulated component and form external contacts.

14. The component according to claim 13, wherein said electrically conductive regions have a cross-section selected from the group consisting of flat cross-sections, trapezoidal cross-sections and T-shaped cross sections.
